(19) United States
(12) Patent Application Publication
(10) Pub. No.: US 2011/0074523 A1
(43) Pub. Date: Mar. 31, 2011

(54) Electronic device

(75) Inventors: Koichi Hasegawa, Kanagawa (JP); Fumio Harima, Kanagawa (JP)

(73) Assignee: RENESAS ELECTRONICS CORPORATION, Kawasaki-shi (JP)

(21) Appl. No.: 12/923,607

(22) Filed: Sep. 29, 2010

(30) Foreign Application Priority Data
Sep. 30, 2009 (JP) 2009-227499

(51) Int. Cl. H03H 7/01

(52) U.S. Cl. 333/175

(57) ABSTRACT

An electronic device includes a semiconductor device; and a mounting substrate mounted with the semiconductor device and connected with predetermined voltages. The semiconductor device includes a filter circuit section configured to output a harmonic component of an input signal other than a desired frequency component to the mounting substrate and output the desired frequency component to an output node of the filter circuit section. The filter circuit section includes an inductor which is larger than a parasitic inductance component in the mounting substrate.

### INCORPORATION BY REFERENCE

The present application claims a priority on convention based on Japanese Patent Application No. 2009-227499 filed on Sep. 30, 2009. The disclosure thereof is incorporated herein by reference.

### TECHNICAL FIELD

The present invention relates to a semiconductor device, a mounting substrate for mounting the semiconductor device, and an electric device including the semiconductor device and the mounting substrate, and more particularly to a semiconductor device including a filter circuit, a mounting substrate for mounting the semiconductor device, and an electric device including the semiconductor device and the mounting substrate.

### BACKGROUND ART

In a microwave radio system, power leakage into a frequency band other than a used frequency is prohibited. For this reason, various types of filters are generally inserted to substantially attenuate low-frequency noise generated from various types of power supplies and a signal processing circuit in a system, a harmonic signal generated from an amplifier of a transmitting and receiving section, and the like. These filter circuits are generally include inductors and capacitors that are passive elements.

Recently, with progress of downsizing a filter module for mounting on a mobile equipment, a spiral inductor and a capacitor patterned on the semiconductor chip are used to further miniature the filter module which was previously configured from a combination of discrete parts. Also, they are mounted on a same semiconductor chip as an active element for amplification in an MMIC (Monolithic Microwave Integrate Circuits).

Meanwhile, the spiral inductor patterned on the semiconductor chip is effective in reducing the size and area, but disadvantage on an aspect of characteristics, and it is difficult to obtain a high Q value in the spiral inductor. Accordingly, a scheme of replacing a part of inductance elements by a bonding wire with a high Q value is employed.

FIGS. 1A to 1C are diagrams showing a conventional semiconductor device having a filter circuit and of a conventional mounting substrate for mounting the semiconductor device. FIG. 1A is a plan view showing an internal structure of the conventional semiconductor device in the neighborhood of the filter circuit on the semiconductor chip including a package. FIG. 1B is a plan view showing a configuration of the mounting substrate for mounting the package of the conventional semiconductor device. FIG. 1C is a cross-sectional view of the semiconductor device in FIG. 1A, when the package is seen from an A direction.

The semiconductor device includes a semiconductor chip 1, a lead frame (LF) mounting area 2, a plurality of lead frame pin terminals 3, a mold resin 4, and a plurality of bonding wires 10a to 10c. The semiconductor chip 1 includes a filter circuit section, a filter circuit input section 7, and a filter circuit output section 8. The filter circuit section includes a plurality of bonding pads 9a to 9c, a plurality of spiral inductor patterns 5a to 5e, and a plurality of capacitor patterns 6a to 6c.

The mounting substrate includes a mounting substrate member 15, mounting substrate front surface plating patterns 11, 12a, and 12b, and a mounting substrate back surface plating pattern 13. The mounting substrate surface plating patterns 11, 12a, and 12b include a package center portion area 11, a pin portion area 12a connected to the package center portion area 11, and a pin portion area 12b which are not connected to the package center portion area. The mounting substrate member 15 includes through-holes 14.

The mounting substrate is mounted on a housing 16. The package including the lead frame mount area 2, the lead frame pin terminal 3, and the mold resin 4 is mounted on the mounting substrate. In this case, the LF mounting area 2 is connected to the package center portion area 11 of the mounting substrate front surface plating pattern, and the lead frame pin terminal 3 is connected to the pin portion areas 12a and 12b of the mounting substrate front surface plating pattern.

The semiconductor chip 1 is mounted on the lead frame mount area 2. The lead frame mount area 2 on which the semiconductor chip 1 is mounted and the plurality of lead frame pin terminals 3 are fixed by the mold resin 4.

One end of each of the plurality of bonding wires 10a to 10c is connected to the lead frame mounting area 2. In addition, the other ends of the plurality of bonding wires 10a to 10c are connected to the plurality of bonding pads 9a to 9c, respectively. In the filter circuit section of the semiconductor chip 1, the plurality of bonding pads 9a to 9c are connected to one ends of the plurality of spiral inductor patterns 5a to 5c, respectively. The other ends of the plurality of spiral inductor patterns 5a to 5c are connected to one ends of the plurality of capacitor patterns 6a to 6c, respectively. The other end of the capacitor pattern 6a is connected to the filter circuit input section 7. The other end of the capacitor pattern 6b is connected to one ends of the plurality of spiral inductor patterns 5d and 5e. The other end of the capacitor pattern 6c is connected to the filter circuit output section 8. The other end of the spiral inductor pattern 5d is connected to the filter circuit input section 7. The other end of the spiral inductor pattern 5e is connected to the filter circuit output section 8.

The package center portion area 11 on the mounting substrate is connected to one end of the through-hole 14a. The other end of the through-hole 14a is connected to the mounting substrate back surface plating pattern 13.

The spiral inductors 5a to 5c are connected to the capacitors 6a to 6c, respectively, to form three resonant circuits. These three resonant circuits are connected to the lead frame mount area 2 via the bonding pads 9a to 9c and the bonding wires 10a to 10c, respectively. These three resonant circuits runs away a frequency component of a harmonic signal to be attenuated, to the lead frame mounting area 2 connected to the ground GND. As the result, the filter circuit section outputs from the filter circuit output section 8, a signal attenuated with the harmonic components of the signal inputted from the filter circuit input section 7.

It is assumed that the filter circuit is separated into three portions a, b, and c. The portion a includes the spiral inductor pattern 5a, the capacitor pattern 6a, the bonding pad 9a, and the bonding wire 10a. The portion b includes the spiral inductor pattern 5b, the capacitor pattern 6b, the bonding pad 9b, and the bonding wire 10b. The portion c includes the spiral inductor pattern 5c, the capacitor pattern 6c, the bonding pad 9c, and the bonding wire 10c.

In this case, with respect to a basic frequency (f0) of an input signal, the portion a and the portion b of the filter circuit have the resonant circuits corresponding to a second harmonic frequency (2f0), and the portion c similarly has a resonant circuit corresponding to a third harmonic frequency (3f0), respectively.

FIG. 2 is a circuit diagram showing an equivalent circuit considering a parasitic component in the filter circuit of the conventional semiconductor device in FIGS. 1A to 1C. The equivalent circuit includes a filter circuit input section 7, a first partial circuit a, a second partial circuit b, a third partial circuit c, two inductances 5d and 5e, two paths 18a and 18b, the ground voltage GND, and a filter circuit output section 8. The first partial circuit a includes a capacitance pattern 6a, a spiral inductance pattern 5a, a bonding wire 10a, and a first path 17a. The second partial circuit b includes a capacitance pattern 6b, a spiral inductance pattern 5b, a bonding wire 10b, and a second path 17b. The third partial circuit c includes a capacitance pattern 6c, a spiral inductance pattern 5c, a bonding wire 10c, and a third path 17c.

The lead frame mounting area 2 that is a connection target of the bonding wires 10a to 10c is not an ideal ground terminal. Actually, the connection between the bonding wires 10a to 10c and the ground terminal is routed through the package center portion area 11 of the mounting substrate surface plating pattern and the through-hole 14d. Accordingly, each of the first to third paths 17a, 17b, and 17c corresponding to these routings has a parasitic inductance component.

On the other hand, the path 18a connected from the bonding wire 10a to the bonding wire 10b via the lead frame mounting area 2 and the path 18b connected from the bonding wire 10b to the bonding wire 10c via the lead frame mounting area 2 have the parasitic inductance components, respectively.

Meanwhile, in the conventional example, since a relation of (lengths of the paths 17a to 17c>>lengths of the paths 18a and 18b) is satisfied, and parasitic inductance components of the paths 17a to 17c and the paths 18a and 18b are approximately proportional to the lengths, a relation of (parasitic inductance components of the paths 17a to 17c>>parasitic inductance components of the paths 18a and 18b) is satisfied. It should be noted that because the parasitic inductances of the paths 17a to 17c are sufficiently smaller than the inductances 5a to 5e in the filter circuit, the parasitic inductance components of the paths 17a to 17c can be regarded as an equivalent value L_GND. In the same manner, the parasitic inductance components of the paths 18a and 18b can be regarded as an equivalent value L_GND_ISO.

The filter circuit input section 7 is connected to one end of the fourth spiral inductance pattern 5d and to one end of the capacitance pattern 6a. The other end of the capacitance pattern 6a is connected to one end of the spiral inductance pattern 5a. The other end of the spiral inductance pattern 5a is connected to one end of the bonding wire 10a. The other end of the bonding wire 10a is connected to one end of the fourth path 18a and to one end of the first path 17a. The other end of the first path 17a is connected to the ground voltage GND.

The other end of the fourth spiral inductance pattern 5d is connected to one end of the fifth spiral inductance pattern 5e and to one end of the capacitance pattern 6b. The other end of the capacitance pattern 6b is connected to one end of the spiral inductance pattern 5b. The other end of the spiral inductance pattern 5b is connected to one end of the bonding wire 10b. The other end of the bonding wire 10b is connected to the other end of the fourth path 18a, to one end of the fifth path 18b, and to one end of the second path 17b. The other end of the second path 17b is connected to the ground voltage GND.

The other end of the fifth spiral inductance pattern 5e is connected to the filter circuit output section 8 and to one end of the capacitance pattern 6c. The other end of the capacitance pattern 6c is connected to one end of the spiral inductance pattern 5c. The other end of the spiral inductance pattern 5c is connected to one end of the bonding wire 10c. The other end of the bonding wire 10c is connected to the other end of the fifth path 18b and to one end of the third path 17c. The other end of the third path 17c is connected to the ground voltage GND.

In conjunction with the above-mentioned description, Patent Literature 1 (JP-A-Heisei 2-34014) discloses a composite semiconductor device which has a transistor having a high input impedance and an internal matching circuit of an inductance and a capacitance to attain an optimum input impedance.

In addition, Patent Literature 2 (JP-A-Heisei 8-274263) discloses a noise filter, which is formed by arranging a first metal wiring in a spiral shape on a semiconductor substrate via a first insulating film. The noise filter is formed by arranging a second metal wiring in a spiral shape via a second insulating film on the first metal wiring to oppose to each other. In the noise filter, the first metal wiring functions as a signal line, and a lead electrode of the second metal wiring and a lead frame on which the semiconductor substrate is adhered by a conductive paste, are connected by a bonding wire so that the second metal wiring and the semiconductor substrate are in a same voltage (grounded).

Moreover, Patent Literature 3 (JP 2002-93845A) discloses an integrated signal filter, which includes a signal filter, an integrated circuit having a plurality of bonding pads, an integrated circuit carrier substrate mounted with the integrated circuit and having a plurality of bonding pads, and a bonding wire connected between two of the bonding pads, and functioning as an inductive element parasitic to the signal filter.

Furthermore, Patent Literature 4 (WO2003/094232) discloses a semiconductor device, which includes a seal substance, a plurality of leads, a tab, a semiconductor chip, a plurality of first conductive wires, and a plurality of second conductive wires. Here, the seal substance includes an insulating resin. The plurality of leads are provided from the inside of the seal substance to the outside along the circumference of the seal substance. The tab has a main surface and a back surface. The semiconductor chip has a main surface and a back surface. The semiconductor chip includes a plurality of electrode terminals on the main surface; and a plurality of circuit sections each including a plurality of semiconductor elements. The plurality of first conductive wires connect the plurality of electrode terminals to the leads. The plurality of second conductive wires connect the plurality of electrode terminals to the main surface of the tab to supply a first voltage to the plurality of electrode terminals. The back surface of the semiconductor chip is fixed on the main surface of the tab. The plurality of circuit sections include a first circuit section and a second circuit section. The plurality of electrode terminals includes a first electrode terminal for inputting an external signal to the first circuit section, a second electrode terminal for supplying the first voltage to the first circuit section, a third electrode terminal connected to the second circuit section, and a fourth electrode terminal for supplying the first voltage to the second circuit section. The plurality of leads include a first lead, a second lead, and a third lead arranged between the first lead and the second lead. The first electrode terminal is connected to the first lead via a conductive wire. The second electrode terminal is connected to the third lead via a conductive wire. The third electrode terminal is connected to the second lead via the conductive wire. The fourth electrode terminal is connected to the tab via a conductive wire. The third lead and the tab are separated from each other.

### Citation List:

[Patent Literature 1]: JP-A-Heisei 2-34014

[Patent Literature 2]: JP-A-Heisei 8-274263

[Patent Literature 3]: JP 2002-93845A

[Patent Literature 4]: WO2003/094232

### SUMMARY OF THE INVENTION

FIG. 5 shows graphs of a simulation result of an ideal signal transmission characteristic, in which a parasitic component is ignored, in a conventional semiconductor filter circuit. FIG. 5 shows a graph in which a basic frequency (f0) of an input signal is 2.45 GHz, and the signal transmission characteristic (S21) of the filter circuit is shown to reject the passage of the second harmonic frequency (2f0) of 4.9 GHz and the third harmonic frequency (3f0) of 7.35 GHz. In the graph, a horizontal axis represents a frequency of the input signal to the filter circuit, and a vertical axis represents the signal passage characteristic of the filter.

In the graph, a first line S(2, 1) represents a signal transmission characteristic of the filter circuit under an ideal ground condition in which a parasitic component is ignored, and a rejection amount of the signal of 2f0 is shown by a marker (1) on a first line S(2, 1) as a ratio of a transmission signal to an input signal. A second line S(4, 3) represents a conventional filter circuit characteristic in a case of presence of a parasitic component, and the rejection amount of the signal of 2f0 is shown by a marker (2) on the second line S(4, 3), in the same manner. In this graph, the first line shows a filter circuit characteristic under the first condition. The second line shows a filter circuit characteristic under the second condition. A third line “Ref” shows the filter circuit characteristic under a criteria condition.

FIG. 3 is a circuit diagram showing an ideal equivalent circuit in a case of ignoring a parasitic component in the conventional semiconductor filter circuit in FIGS. 1A to 1C. The circuit diagram shown in FIG. 3 is the same as the circuit diagram in which the two paths 18a and 18b and three paths 17a to 17c are removed from the circuit diagram in FIG. 2. Accordingly, further detailed explanation will be omitted.

In a case that the structure shown in FIGS. 1A to 1C is employed as a specification of actual assembly while a circuit design is carried out in the calculation simulation by using the ideal equivalent circuit of the filter circuit shown in FIG. 3, an influence appears due to the parasitic inductance components included in the two paths 18a and 18b and the three paths 17a to 17c in the equivalent circuit of FIG. 2. That is, a relation of (the parasitic inductance component (L_GND) in three paths 17a to 17c>>the parasitic inductance component (L_GND_ISO) in two paths 18a and 18b) is satisfied.

As a result, by the filter circuit a and the filter circuit b configuring a resonant circuit of 2f0, a frequency component (2f0 in this example) is assumed to be rejected by connecting the frequency component of 2f0 to the ground voltage GND. However, actually, the frequency component of 2f0 appears on the filter circuit output section 8 via the filter circuit a, the corresponding path 18a, and the filter circuit b. For this reason, the rejection amount is smaller than that under an ideal condition in the conventional example.

In addition, the parasitic inductance components due to the paths 17a to 17c vary depending on not the semiconductor device in the package but a length or a diameter of the through-hole 14 formed in the mounting substrate 15. Accordingly, when a pattern of the mounting substrate varies, the rejection amount of the filter circuit also changes consequently.

In an aspect of the present invention, an electronic device includes: a semiconductor device; and a mounting substrate mounted with the semiconductor device and connected with predetermined voltages. The semiconductor device includes a filter circuit section configured to output a harmonic component of an input signal other than a desired frequency component to the mounting substrate and output the desired frequency component to an output node of the filter circuit section. The filter circuit section includes an inductor which is larger than a parasitic inductance component in the mounting substrate.

According to an electronic device of the present invention, in a filter circuit of a semiconductor device, a rejection amount equal to that in an ideal case in which a parasitic inductance is not included can be obtained by suppressing reduction of a rejection amount of harmonic components caused by the parasitic inductance, and thus a rejection amount of the harmonic component increases.

### BRIEF DESCRIPTION OF THE DRAWINGS

The above and other objects, advantages and features of the present invention will be more apparent from the following description of certain embodiments taken in conjunction with the accompanying drawings, in which:

FIG. 1A is a plan view showing an internal structure of a conventional semiconductor device in the neighborhood of a filter circuit;

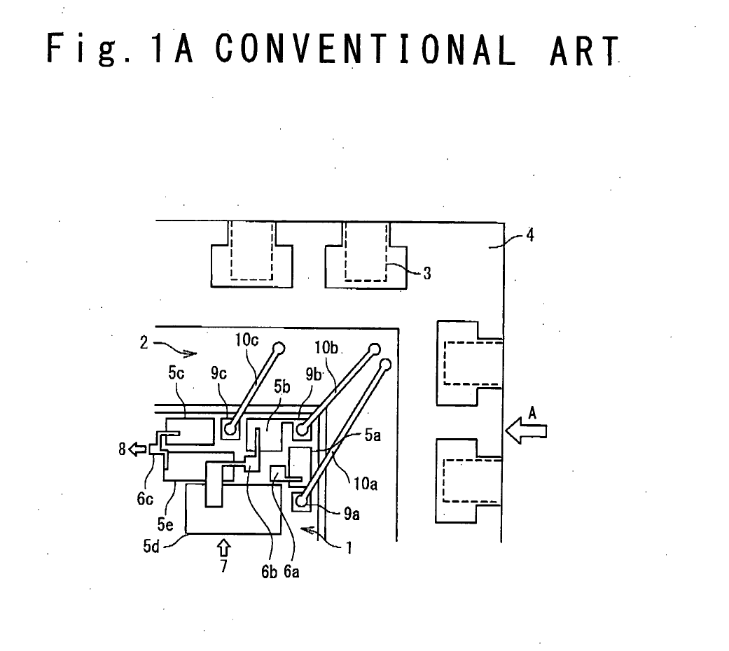

FIG. 1B is a plan view showing a configuration of a mounting substrate for mounting a package of the conventional semiconductor device;

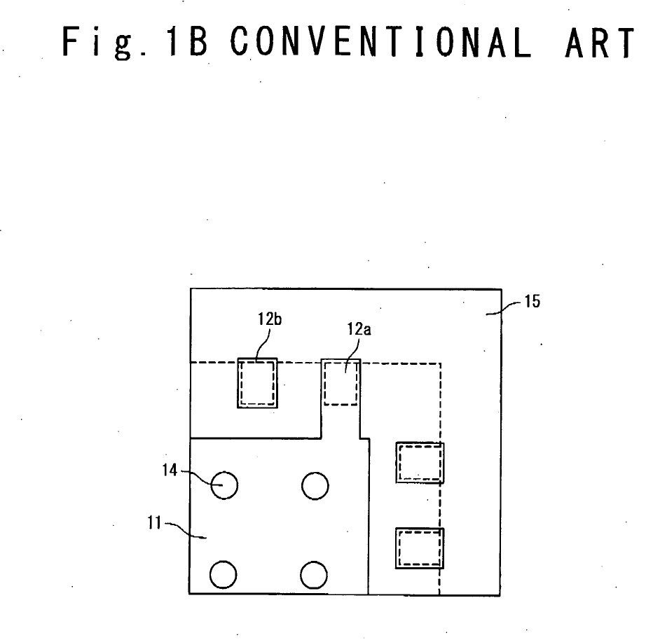

FIG. 1C is a cross-sectional view of the conventional semiconductor device in FIG. 1A;

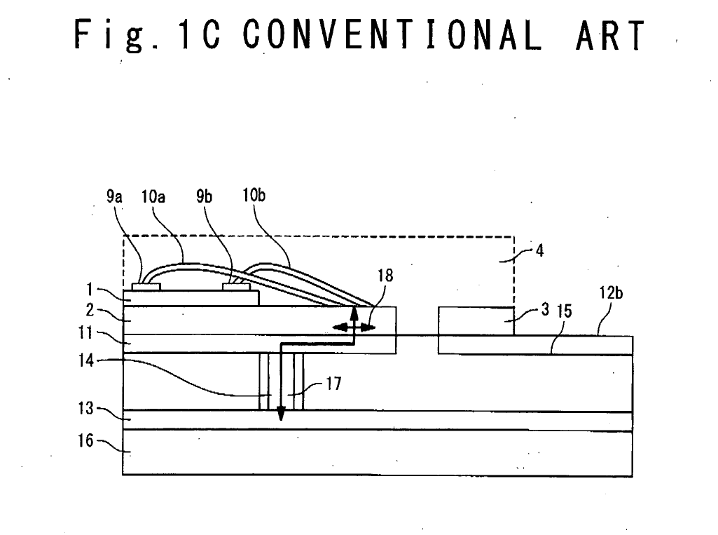

FIG. 2 is a circuit diagram showing an equivalent circuit of the filter circuit in consideration of parasitic components;

FIG. 3 is a circuit diagram showing an ideal equivalent circuit in a case of ignoring parasitic components;

FIG. 4A is a plan view showing an internal structure of a semiconductor device according to an embodiment of the present embodiment which has a filter circuit on a semiconductor chip;

FIG. 4B is a plan view showing a pattern of a mounting substrate mounted with a package of the semiconductor device;

FIG. 4C is a cross-sectional view of an electronic device mounted with the semiconductor device on the mounting substrate along a broken line;

FIG. 5 shows graphs of a simulation result of a signal transmission characteristic;

FIG. 6 is a graph showing a simulation result of the characteristics of the filter circuit of an electronic device according to the present invention;

FIG. 7 is a cross sectional view of the electronic device according to a second embodiment of the present invention; and

FIG. 8 is a table showing a simulation calculation result of a second harmonic frequency (2f0) rejection amount in the signal passage characteristic of the filter circuit of the electronic device according to the present invention.

### DESCRIPTION OF EMBODIMENTS

Hereinafter, a semiconductor device mounted on a mounting substrate according to the present invention will be described in detail with reference to the attached drawings.

### First Embodiment

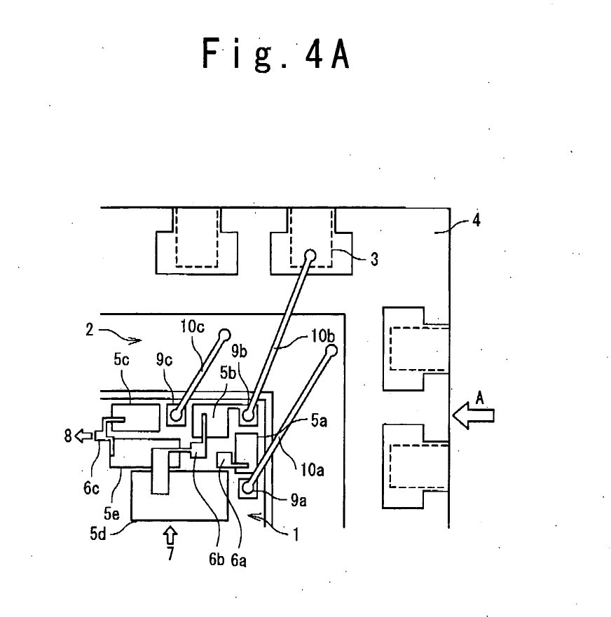

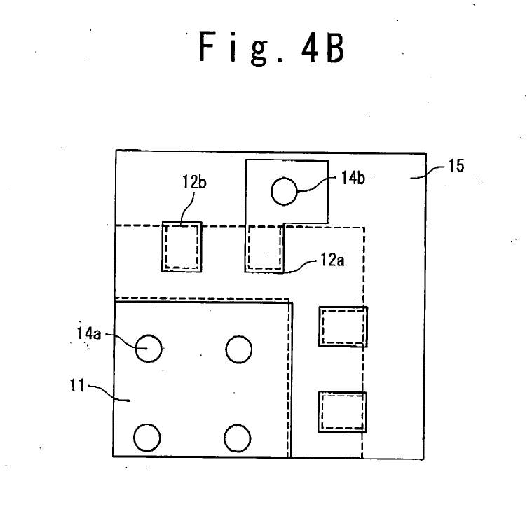

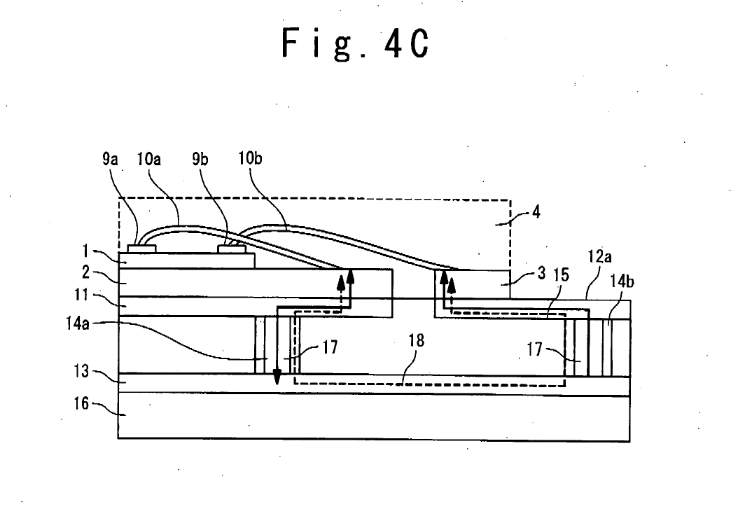

FIG. 4A to FIG. 4C are diagrams showing a configuration of an electronic device according to a first embodiment of the present invention. FIG. 4A is a plan view showing an internal structure with a package portion of a semiconductor device in the present embodiment which has a filter circuit on a semiconductor chip. FIG. 4B is a plan view showing a pattern of the mounting substrate mounted with the package of the semiconductor device according to the present embodiment. FIG. 4C is a cross-sectional view of the electronic device mounted with the semiconductor device in FIG. 4A on the mounting substrate in FIG. 4B along a broken line, when seen from the A direction.

The electronic device according to the present embodiment includes a semiconductor chip 1, an LF (lead frame) mounting area 2, a plurality of lead frame pin terminals 3, a mold resin 4, and a plurality of bonding wires 10a to 10c. The semiconductor chip 1 includes a filter circuit section, a filter circuit input section 7, and a filter circuit output section 8. The filter circuit section includes a plurality of bonding pads 9a to 9c, a plurality of spiral inductance patterns 5a to 5e, and a plurality of capacitance patterns 6a to 6c.

The mounting substrate according to the present embodiment includes a mounting substrate member 15, mounting substrate front surface plating patterns 11, 12a, and 12b, and a mounting substrate back surface plating pattern 13. The mounting substrate front surface plating patterns 11, 12a, and 12b include a package center portion area 11, and a pin portion areas 12a and 12b which are not connected to the package center area. The mounting substrate member 15 includes through-holes 14a and 14b.

The mounting substrate according to the embodiment is mounted on a housing 16. The package including the lead frame mounting area 2, the lead frame pin terminal 3, and the mold resin 4 is mounted on the mounting substrate. In this case, the lead frame mounting area 2 is connected to the package center portion area 11 of the mounting substrate front surface plating pattern, and the lead frame pin terminal 3 is connected to the pin portion areas 12a and 12b of the mounting substrate front surface plating pattern,

The semiconductor chip 1 of the semiconductor integrated circuit is mounted on the lead frame mounting area 2. The lead frame mounting area 2 on mounted with the semiconductor chip 1 and the plurality of lead frame pin terminals 3 are fixed by the mold resin 4.

One end of each of the plurality of bonding wires 10a and 10c is connected to the lead frame mounting area 2, and one end of the bonding wire 10b is connected to the lead frame pin terminal 3. In addition, the other end of each of the plurality of bonding wires 10a to 10c is connected to the plurality of bonding pads 9a to 9c, respectively. In the filter circuit section of the semiconductor chip 1, the plurality of bonding pads 9a to 9c are connected to one ends of the plurality of spiral inductance patterns 5a to 5c, respectively. The other ends of the plurality of spiral inductance patterns 5a to 5c are connected to one ends of the plurality of capacitance patterns 6a to 6c, respectively. The other end of the capacitance pattern 6a is connected to the filter circuit input section 7. The other end of the capacitance pattern 6b is connected to one ends of the plurality of spiral inductance patterns 5d and 5e, respectively. The other end of the capacitance pattern 6c is connected to the filter circuit output section 8. The other end of the spiral inductance pattern 5d is connected to the filter circuit input section 7. The other end of the spiral inductance pattern 5e is connected to the filter circuit output section 8.

The package center portion area 11 on the mounting substrate surface is connected to one end of the through-hole 14a. The other end of the through-hole 14a is connected to the mounting substrate back surface plating pattern 13.

The spiral inductances 5a to 5c are connected to the capacitances 6a to 6c, respectively, to from three resonant circuits. These three resonant circuits are connected to the lead frame mounting area 2 via the bonding pads 9a to 9c and the bonding wires 10a to 10c, respectively. These three resonant circuits connect a frequency component of a harmonic signal to be attenuated, to the lead frame mounting area 2 connected to the GND. As the result, the filter circuit section carries out an operation for outputting a signal obtained by attenuating the harmonic components with respect to the signal inputted from the filter circuit input section 7 from the filter circuit output section 8.

This filter circuit section will be considered by being separated in three portions, a, b, and c. The portion a includes a spiral inductance pattern 5a, a capacitance pattern 6a, a bonding pad 9a, and a bonding wire 10a. The portion b includes a spiral inductance pattern 5b, a capacitance pattern 6b, a bonding pad 9b, and a bonding wire 10b. The portion c includes a spiral inductance pattern 5c, a capacitance pattern 6c, a bonding pad 9c, and a bonding wire 10c.

In this case, with respect to a basic frequency (f0) of an input signal, the portion a and portion b of the filter circuit section have the resonant circuits corresponding to second harmonic frequency (2f0), and the portion c similarly has a resonant circuit corresponding to a third harmonic frequency (3f0), respectively.

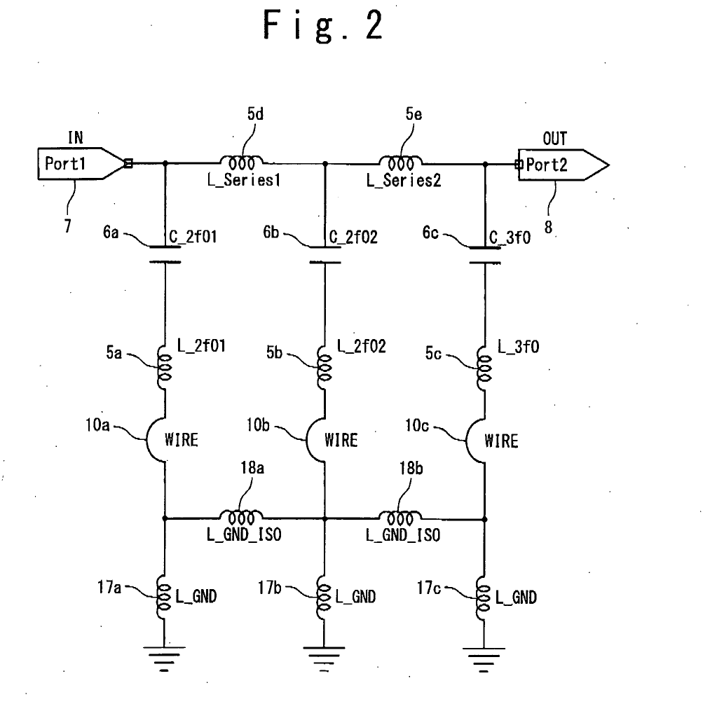

FIG. 2 is a circuit diagram showing an equivalent circuit of the filter circuit of the electronic device according to the present embodiment in FIGS. 4A to 4C in consideration of parasitic components. The equivalent circuit includes the filter circuit input section 7, a first partial circuit a, a second partial circuit b, a third partial circuit c, two inductances 5d and 5e, two paths 18a and 18b, the ground voltage GND, and the filter circuit output section 8. The first partial circuit a includes the capacitance pattern 6a, a spiral the inductance pattern 5a, the bonding wire 10a, and the first path 17a. The second partial circuit b includes the capacitance pattern 6b, the spiral inductance pattern 5b, the bonding wire 10b, and the second path 17b. The third partial circuit c includes the capacitance pattern 6c, the spiral inductance pattern 5c, the bonding wire 10c, and the first path 17c.

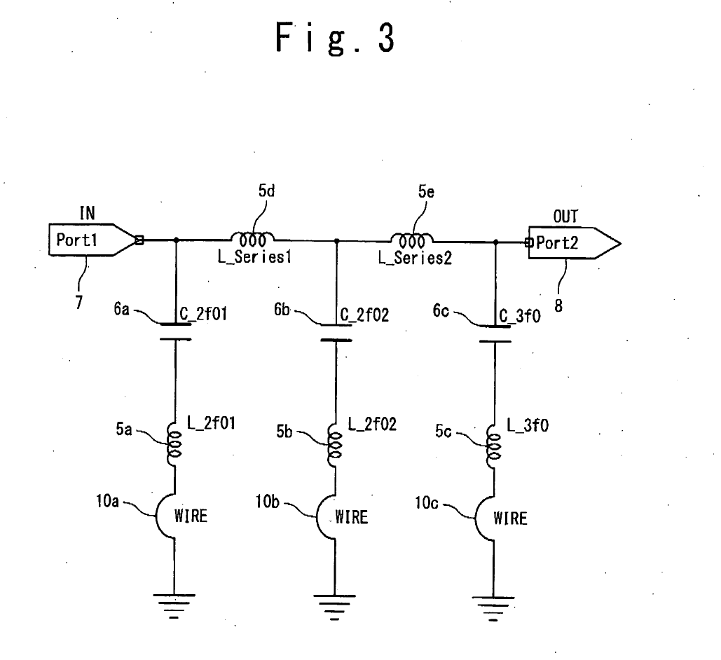

The lead frame mounting area 2 as connection targets of the respective bonding wires 10a to 10c does not have the ideal ground voltage GND. In actual, the connection between each of the bonding wires 10a to 10c and the ground voltage GND is routed through the package center portion area 11 of the mounting substrate front surface plating pattern and the through-hole 14d. Accordingly, each of the first to third paths 17a, 17b, and 17c corresponding to these routings has a parasitic inductance component. Meanwhile, an ideal equivalent circuit ignoring the parasitic component is the same circuit as shown in FIG. 3.

On the other hand, the path 18a connected to the bonding wire 10b via the lead frame mounting area 2 from the bonding wire 10a and the path 18b connected to the bonding wire 10c via the lead frame mounting area 2 from the bonding wire 10b are also have parasitic inductance components, respectively.

It should be noted that in the present embodiment, a relation of (length of the path 18>length of the path 17) is satisfied and the parasitic inductance components of the paths 17a to 17c and the paths 18a and 18b are approximately proportional to the respective lengths. Accordingly, a relation of (parasitic inductance components of the paths 17a to 17c<parasitic inductance components of the paths 18a and 18b) is satisfied. Here, the parasitic inductances of the paths 17a to 17c are substantially smaller than the inductances 5a to 5e in the filter circuit, and thus the parasitic inductance components of the paths 17a to 17c can be regarded as an equivalent value L_GND, respectively. In the same manner, the parasitic inductance components of the paths 18a and 18b can be regarded as an equivalent value L_GND_ISO.

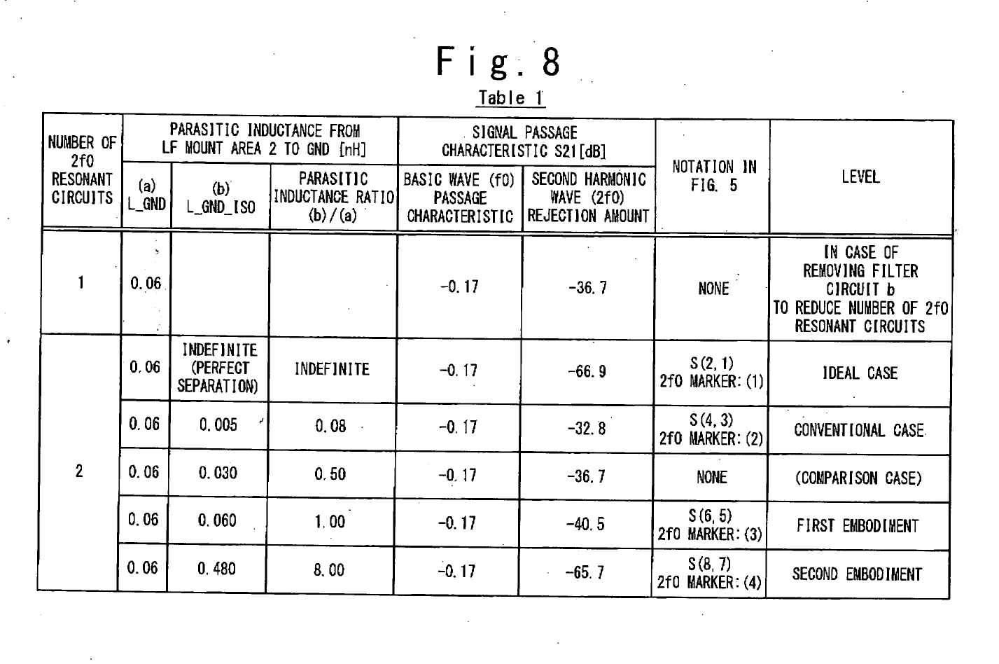

The table 1 in FIG. 8 shows a simulation calculation result of a second harmonic frequency (2f0) rejection amount in the signal passage characteristic of the filter circuit of the electronic device according to the present invention. The table 1 shows change of the signal passage characteristic according to change of the parasitic inductance components from the lead frame mounting area 2 to which the bonding wires 10a to 10c (GND wires) are connected, to the housing 16 serving as the ground voltage GND via the paths 17a to 17c and the paths 18a and 18b.

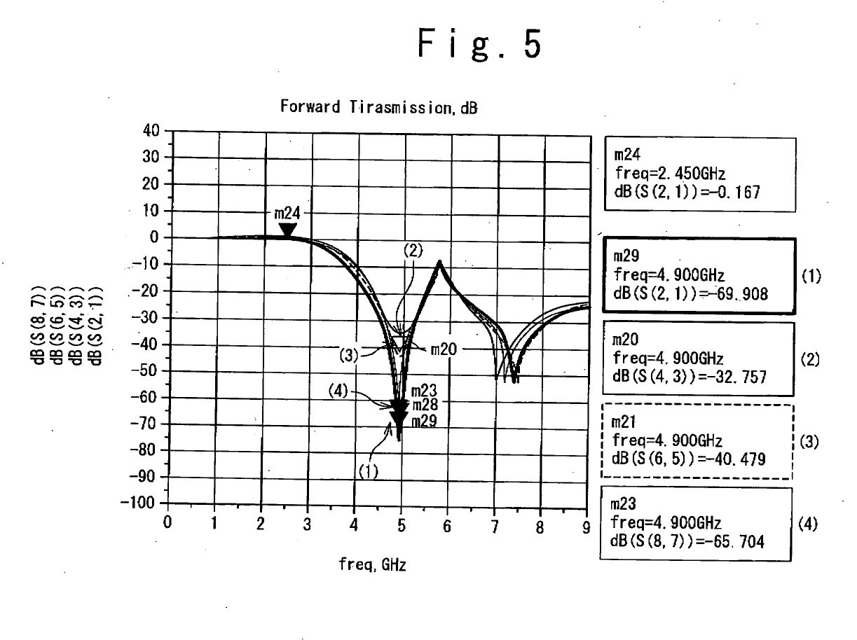

FIG. 5 is a graph showing the simulation calculation result of the signal passage characteristic of the filter circuit of the electronic device according to the present invention. The graph shows the signal passage characteristic (S21) of the filter circuit which blocks (rejects) the second harmonic frequency (2f0) of 4.9 GHz and the third harmonics (3f0) of 7.35 GHz when the basic frequency (f0) of the input signal is 2.45 GHz. In the graph, a horizontal axis represents frequency of the input signal into the filter circuit and a vertical axis represents the signal passage characteristic. Four graphs drawn in FIG. 5 correspond to S(2,1) to S(8,7) in an item “Notation in FIG. 5” of the table 1, respectively, and the rejection amount of 2f0 is represented in markers (1) to (4) as a ratio of the passage signal to the input signal, which shows that the rejection amount is larger when the value is smaller.

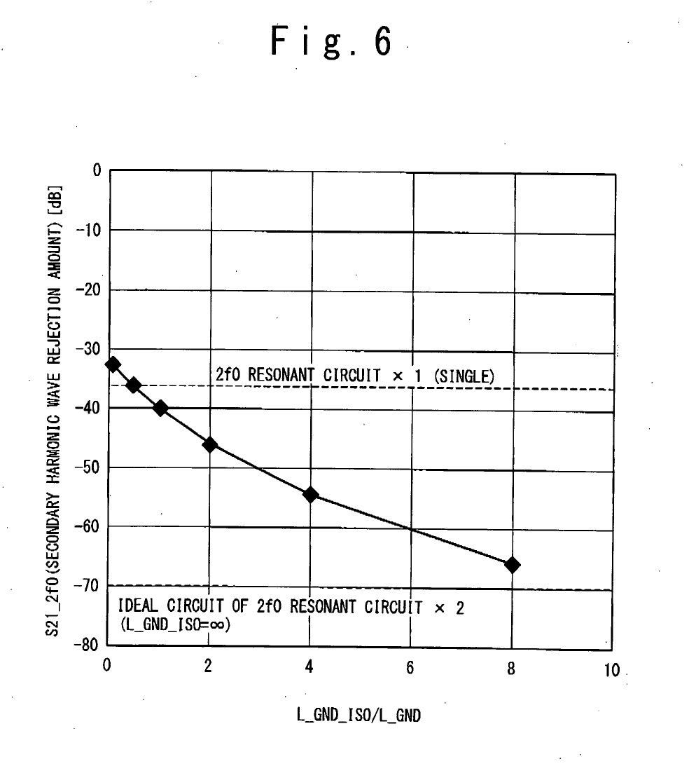

FIG. 6 is a graph showing a simulation result of the characteristics of the filter circuit of the electronic device according to the present invention. In the graph, a horizontal axis represents a ratio of L_GND_ISO/L_GND, and a vertical axis represents the rejection amount of 2f0 in the filter circuit.

The parasitic inductances L_GND in the paths 17a to 17c vary depending on a condition of a through-hole and the like. As the parasitic inductance L_GND in the table 1, a result is used of an electromagnetic field simulation when a substrate thickness is 0.2 mm, a radius of the through-hole is 0.2 mm, and a plating thickness is 17 μm. In the result of the electromagnetic field simulation, the inductance per hole was 0.06 nH. Consequently, in the table 1, the parasitic inductance L_GND is 0.06 nH, and the parasitic inductance L GND _ISO in the paths 18a and 18b was represented by a ratio to the L_GND.

As the result of the simulation, in a case of (L_GND _ISO/L_GND<0.5), the rejection amount when two resonant circuits are employed is −32.8 dB, and accordingly it could be seen that the rejection amount is smaller than −36.7 dB that is the rejection amount when one resonant circuit is employed. In addition, it could be seen that, in a case of (L_GND_ISO/L_GND=0.5), the rejection amount in a case of one resonant circuit and the rejection amount in a case of two resonant circuits become equally −36.7 dB. In a case of (L_GND_ISO/L_GND>0.5), the rejection amount becomes large by increasing the number of resonant circuit to two.

In the present embodiment, since the parasitic inductance ratio corresponding to (L_GND_ISO/L_GND≧1) can be obtained, the rejection amount becomes −40.5 dB, which shows the rejection amount is increased by 7.7 dB in comparison with the conventional example.

### Second Embodiment

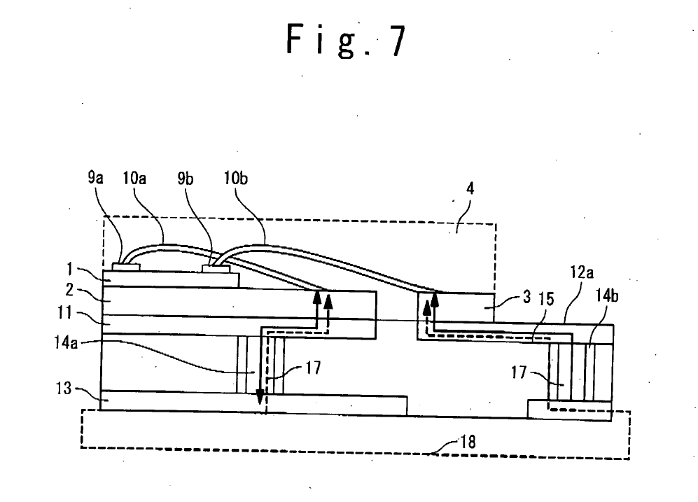

FIG. 7 is a cross-section view of an electronic device according to a second embodiment of the present invention. In the same manner as that of the first embodiment, the electronic device according to the present embodiment also includes a semiconductor device, and a mounting substrate for mounting the semiconductor device. Meanwhile, a top view of the internal structure of the electronic device including a package in the neighborhood of a filter circuit section is the same as that of FIG. 4A, and accordingly the description is omitted. In addition, a top view showing a pattern of a substrate for mounting the semiconductor device according to the present embodiment having the filter circuit section on a semiconductor chip is the same as that of FIG. 4B, and accordingly the description is omitted. In other words, FIG. 7 is a cross-section view of the semiconductor device in FIG. 4A on the mounting substrate in FIG. 4B along a broken line, when seen in an A direction.

A difference between the electronic device according to the present embodiment and the electronic device according to the first embodiment in the present invention is the mounting substrate back surface plating pattern 13. That is, in the electronic device according to the first embodiment of the present invention, the mounting substrate back surface plating pattern 13 is shared by the two resonant circuits a and b. However, in the semiconductor device according to the present embodiment, the mounting substrate back surface plating pattern 13 is separated between the two resonant circuits a and b.

Other configurations of the electronic device according to the present embodiment are the same as those of the first embodiment of the present invention, and accordingly the detailed description will be omitted.

A simulation result under a condition of present embodiment corresponds to “Second Embodiment” in a row of the table 1, S(8, 7) and a 2f0 marker (4) in the graph of FIG. 5, and a point corresponding to the value of “8” in a horizontal axis in the graph of FIG. 6. As it could be understood from these results, according to the present embodiment, the rejection amount is obtained which is substantially equal to that in an ideal circuit.

The reason will be described. According to the present embodiment, the relation (L_GND_ISO/L_GND>>1), that is, (L_GND_ISO>>L_GND) can be realized in a same resonant circuit. As the result, a phenomenon that a frequency component to be essentially rejected by being fallen into the GND returns via the resonant circuit a, the corresponding path 18, and the resonant circuit b to appear in the filter circuit output section 8 again can be substantially suppressed. Meanwhile, the frequency component to be rejected in the present embodiment is the harmonic signal having the frequency of 2f0.

As described above, according to the present invention, a following effect can be obtained. That is, the rejection amount equivalent to that in the ideal case in which the parasitic inductance is not included can be obtained in the filter circuit having a ground wire and formed on the semiconductor chip, by suppressing the reduction of the rejection amount of the harmonic components caused by the parasitic inductance. Thus, the rejection amount of the harmonic component increases.

Although the present invention has been described above in connection with several embodiments thereof, it would be apparent to those skilled in the art that those embodiments are provided solely for illustrating the present invention, and should not be relied upon to construe the appended claims in a limiting sense.

What is claimed is:

1. An electronic device comprising:
a semiconductor device; and
a mounting substrate mounted with said semiconductor device and connected with predetermined voltages,
wherein said semiconductor device comprises a filter circuit section configured to output a harmonic component of an input signal other than a desired frequency component to said mounting substrate and output said desired frequency component to an output node of said filter circuit section, and
wherein said filter circuit section comprises an inductor which is larger than a parasitic inductance component in said mounting substrate.

2. The electronic device according to claim 1, wherein said filter circuit section comprises a resonant circuit section provided for a frequency band of said harmonic component.

3. The electronic device according to claim 2, wherein said resonant circuit section comprises:
said inductor; and
a capacitor connected in series with said inductor,
wherein a combination of said inductor and said capacitor corresponds to the frequency band of said harmonic component.

4. The electronic device according to claim 3, wherein said filter circuit section further comprises another resonant circuit section in addition to said resonant circuit section, and
wherein said another resonant circuit section is provided for another frequency band, of said harmonic component which is different from the frequency band.

5. The electronic device according to claim 4, wherein said filter circuit section comprises:
an input section configured to input said input signal;
an output section configured to output said desired frequency component of said input signal from said output node; and
an inter-section inductor connected between said input section and said output section,
wherein one ends of said resonant circuit section and said another resonant circuit section are connected with ends of said inter-section inductor, respectively, and
wherein the other ends of said resonant circuit section and said another resonant circuit section are connected with ends of said parasitic inductance component in said mounting substrate.

6. The electronic device according to claim 5, wherein said mounting substrate comprises;
a first back surface ground pattern connected with one of the ends of said parasitic inductance component; and
a second back surface ground pattern connected with the other end of said parasitic inductance component, and
wherein said first and second back surface ground patterns are insulated from each other.
